(19) United States
(12) Patent Application Publication
(10) Pub. No.: US 2025/0155380 A1
(43) Pub. Date: May 15, 2025

(54) OPTICAL INSPECTION DEVICE

(71) Applicant: Carl Zeiss SMT GmbH, Oberkochen (DE)

(72) Inventor: Maximilian Henning, Huettlingen (DE)

(21) Appl. No.: 18/938,487

(22) Filed: Nov. 6, 2024

(30) Foreign Application Priority Data
Nov. 9, 2023 (DE) 102023131119.0

(51) Int. Cl. G01N 21/95; G03F 1/22; G03F 7/00

(52) U.S. Cl. CPC G01N 21/9501; G03F 1/22; G03F 7/70033; G03F 7/706845; G03F 7/70775

(57) ABSTRACT

Disclosed is an optical inspection device for elements pertaining to semiconductor lithography, comprising an imaging device for generating an image of an element, said imaging device being arranged in a first partial volume, and a second partial volume comprising a holding device for receiving the element. A separating element is arranged between the two partial volumes. Included is a position measuring device comprising reference marks for emission of electromagnetic radiation used in the position measuring device and the reference marks are respectively connected to the imaging device and the holding device. The separating element comprises a partition wall having an opening. The opening serves for image recording by the imaging device and the electromagnetic radiation which emanates from the reference mark mounted on the imaging device and proceeds in the position measuring device passes through the opening.

### CROSS-REFERENCE TO RELATED APPLICATIONS

The present application claims the priority of the German patent application DE 10 2023 131 119.0, filed on Nov. 9, 2023, the content of which is fully incorporated herein by reference.

### TECHNICAL FIELD

This disclosure relates to an optical inspection device, in particular a mask inspection system for photomasks pertaining to semiconductor lithography.

### BACKGROUND

Such inspection devices are used to ascertain the state of photomasks used in semiconductor lithography; in particular also to identify defects that have occurred during production or use of the corresponding masks, in order to enable a subsequent repair of a mask.

Such a system usually comprises an imaging device, by which a mask arranged on a holding device, a so-called mask holder, is recorded section by section, step by step or else in a scanning fashion.

With increasing prevalence of EUV lithography, i.e. a form of semiconductor lithography using extremely short wavelengths, in particular wavelengths of a few nanometres, special measures are required for inspection and also for handling of the photomasks.

In particular, the inspection of the masks usually needs to take place in a vacuum environment. Usually in this case the imaging devices and the masks to be examined are arranged in two different partial volumes, each conditioned independently, and between the partial volumes there remains just a small opening for the passage of the electromagnetic radiation used for examining the mask.

However, for reliable imaging of the mask it is necessary for the relative position of the imaging device with respect to the mask to be examined to be known as exactly as possible or else to be rapidly controllable as exactly as possible. This necessitates detecting the respective positions of the involved elements as accurately as possible. Position measuring devices such as interferometers, for example, are typically used in this case. In general, these position measuring devices detect the position of the mask holder and thus indirectly the position of the mask.

In this context, it is advantageous if the position information of both measured components, i.e. of the imaging device and also of the examined mask, is recorded by the same measuring device in order that the relative position of imaging device and mask can be determined as simply as possible. However, this joint measurement is made more difficult by the arrangement of the imaging device and the mask in different partial volumes.

### SUMMARY

It is an object of this disclosure to specify a device which ensures that the relative position of an imaging device and of a mask to be examined, or an element to be examined, is determined as simply and precisely as possible.

In general, in one aspect, disclosed is an optical inspection device that comprises an imaging device for generating an image of an element, said imaging device being arranged in a first partial volume, and a second partial volume comprising a holding device for receiving the element. In this case, a separating element is arranged between the two partial volumes. Furthermore, the inspection device comprises at least one position measuring device for ascertaining the position and orientation of the imaging device and the holding device, wherein the position measuring device comprises reference marks for emission of electromagnetic radiation used in the position measuring device. Within the meaning of the present application, emission should be understood in particular also to mean reflection of incident radiation by the reference marks. The reference marks are respectively connected to the imaging device and the holding device.

In this case, the separating element comprises a partition wall having an opening, wherein the opening serves for image recording by the imaging device and wherein the electromagnetic radiation which emanates from the reference mark mounted on the imaging device and proceeds in the position measuring device passes through the opening.

In this way, the opening between the partial volumes can be kept small, thereby facilitating the maintenance of different atmospheric conditions in the partial volumes. Overall, the design can also be made significantly more compact by virtue of the measures disclosed and exchange of the imaging device in the field, i.e. at the site of use, is simplified.

In one advantageous variant, at least two position measuring devices and at least two reference marks mounted on the imaging device are present, wherein the beam paths of the electromagnetic radiation which emanates from the reference marks and proceeds in the position measuring devices extend obliquely with respect to one another.

In particular, the beam paths of the electromagnetic radiation which emanates from the reference marks and proceeds in the position measuring devices can cross one another.

The element, as has already been mentioned, can be a photomask for semiconductor lithography, for example for EUV lithography; in particular, the optical inspection device can be a mask inspection system for photomasks pertaining to EUV lithography.

The photomask can have an aspect ratio of between 1:1 and 1:3, preferably between 1:1 and 1:2, particularly preferably of 1:1 or 1:2; it can be of substantially rectangular design. The photomask can be preferably 5 to 7 inches (12.7 to 17.78 cm) in length and width, particularly preferably 6 inches (15.24 cm) in length and width. As an alternative thereto, the photomask can be 5 to 7 inches (12.7 to 17.78 cm) in width and 10 to 14 inches (25.4 to 35.56 cm) in length, preferably 6 inches (15.24 cm) in width and 12 inches (30.48 cm) in length.

In one advantageous embodiment, the position measuring device can be an interferometer.

In this case, the interferometer can operate in particular at a different wavelength from that of the radiation used for image recording, for example at 200 nm to 1700 nm, preferably 400 nm to 800 nm. In this case, the electromagnetic radiation emanating from the reference marks is generated by virtue of the reference marks being embodied as reflectors which are illuminated in the interferometer and reflect back the incident radiation in a known manner in the beam path of the interferometer.

Furthermore, at least one position measuring device can be embodied in such a way that electromagnetic radiation which emanates from a reference mark on the imaging device and reaches the position measuring device enters the position measuring device in that partial volume in which the imaging device is also arranged.

In another variant, at least one position measuring device can be embodied in such a way that electromagnetic radiation which emanates from a reference mark on the holding device and proceeds in the position measuring device proceeds completely in that partial volume in which the holding device is also arranged.

This can be achieved for example by at least parts of a position measuring device being inserted into the separating element in such a way that a radiation entrance opening for electromagnetic radiation which emanates from a reference mark on the holding device and proceeds in the position measuring device is arranged in the same partial volume as the holding device, whereas a radiation entrance opening for electromagnetic radiation which emanates from a reference mark on the imaging device and proceeds in the position measuring device is arranged in the same partial volume as the imaging device.

Other aspects, embodiments, and advantages follow.

### DESCRIPTION OF DRAWINGS

Exemplary embodiments and variants are explained in greater detail below with reference to the drawing, in which:

FIG. 1 shows a mask inspection system for examining photomasks,

FIG. 2 shows an alternative to the arrangement shown in FIG. 1,

FIG. 3 shows a further embodiment; and

FIG. 4 shows a further embodiment.

### DETAILED DESCRIPTION

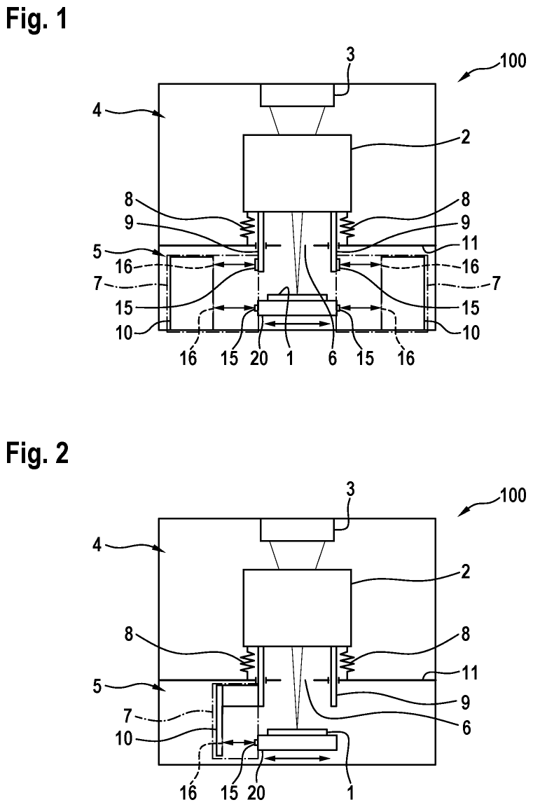

FIG. 1 shows schematically an optical inspection device which is embodied as a mask inspection system 100 for examining elements, photomasks for EUV lithography in the example shown. In such systems—unlike in inspection systems for masks for longer wavelengths—the photomasks are not recorded in segments and in stationary fashion, rather a scan of the entire mask surface is generally performed. In this case, a mask 1 is moved through in scanning fashion beneath an imaging device 2, this being illustrated by the double-headed arrow (not given a reference sign) in FIG. 1. In this case, the mask 1 is arranged on a movable holding device 20, a so-called mask holder.

The figure furthermore illustrates an image sensor 3, onto which the imaging device 2 images the surface of the mask 1. In this case, the image sensor 3 can be embodied as a TDI sensor—similar to the sensors used in linear array cameras.

In this case, the imaging device 2 and the image sensor 3 are situated in a first partial volume embodied as a vacuum chamber 4, whereas the mask 1 arranged on the mask holder 20 is situated in a further partial volume embodied as a vacuum chamber 5, which is separated from the vacuum chamber 5 by a separating element embodied as a partition wall 11. The vacuum chamber 5 can—in contrast to the illustration shown—in particular also be embodied in the form of a box, and in that case the box can be situated within the vacuum chamber 4. Decoupling elements 8 are arranged between the imaging device 2 and the vacuum chamber 4, and cause the imaging device 2 to be at least partly decoupled from the vacuum chamber 4.

The separated vacuum chambers 4 and 5 are necessary in this case in order to minimize contaminations; what is more, the chambers 4 and 5 usually also contain different atmospheres or media. There is an opening 6 situated between the two vacuum chambers 4 and 5, through which opening the light emanating from the mask 1 passes and reaches the imaging device 2.

Owing to the scanning movement of the mask 1, but also owing to ambient influences such as vibrations of the associated floor of the hall or the like, mechanical disturbances are introduced, however, which in the absence of further measures would lead to an offset of the imaging device 2 relative to the mask 1 during the scanning process. The image quality would be adversely affected by such an offset; it is therefore desirable for the imaging device 2 and the mask 1 to be in a fixed spatial relationship with respect to one another during the scan as well—apart from the scanning movement. It is therefore necessary to track the mask 1 to the imaging device 2. For this purpose, it is necessary to know the positions of the mask 1 and the imaging device 2 in a common coordinate system. In order to determine these positions, the interferometers 7 are employed as position measuring devices, which interferometers can be embodied as differential interferometers, for example.

Reference elements 9 are furthermore discernible in the figure, which reference elements are fixedly connected to the imaging device 2, are illustrated as rods in the figure, project into the vacuum chamber 5 through the partition wall 11 between the two vacuum chambers 4 and 5 and comprise reference marks embodied as sensor targets 15, which can be embodied as specularly reflective surfaces and serve as references of the interferometers 7. The measurement beams proceeding in the interferometer 7 and passing through the radiation windows 16, which measurement beams are illustrated by double-headed arrows (not given a reference sign) in the figure, in this case reach the sensor targets 15 of the interferometer 7 and, after a reflection at the sensor targets 15, enter a transmitting/receiving part 10 of the interferometer 7 through the radiation windows 16 again, which transmitting/receiving part can contain for example a radiation source (not illustrated separately in FIG. 1) and a receiving device (likewise not illustrated in FIG. 1) of the interferometer 7.

Like the imaging device 2, the mask holder 20 is also provided with sensor targets 15, which likewise serve for reflecting the measurement beams of the interferometer 7. This makes it possible to determine and optionally control the relative position of the mask holder 20 (and thus of the mask 1) and of the imaging device 2.

An alternative to the arrangement shown in FIG. 1 is found in FIG. 2. There a partial region of the interferometer 7 is fixedly connected to the imaging device 2 and participates in the movements thereof. The relative position of the imaging device 2 with respect to the mask 1 can be determined comparatively easily in this way.

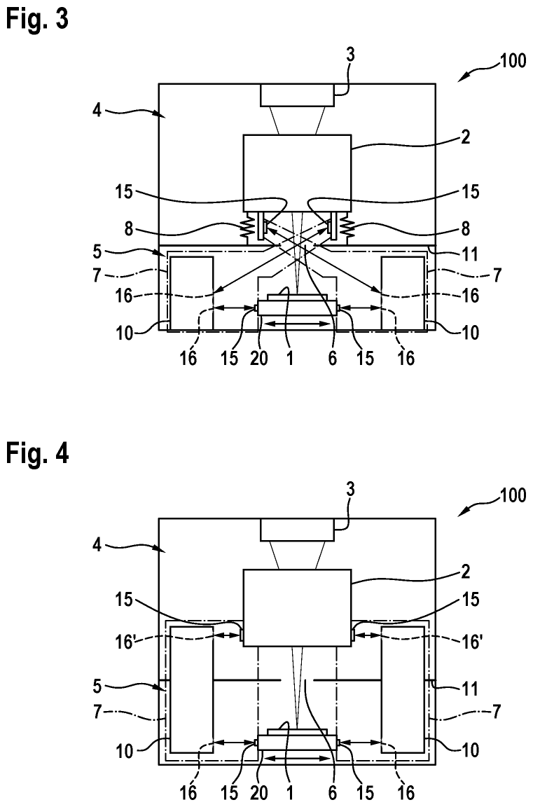

FIG. 3 shows one embodiment, in which the sensor targets 15 assigned to the imaging device 2 are situated in the same vacuum chamber 4 as the imaging device 2. This is achieved in the example shown by virtue of the measurement beams of the interferometers 7 proceeding obliquely and passing through the opening 6 in the partition wall 11 between the vacuum chambers 4 and 5, which is also used for the image recording by the imaging device 2. The beam paths of the electromagnetic radiation which emanates from the sensor targets 15 or is reflected at the latter thus cross one another in the example shown. A skew progression of the beam paths is also conceivable. The opening 6 between the vacuum chamber 4 and the vacuum chamber 5 can be kept comparatively small in this way. Furthermore, in this way sensor targets 15 can be mounted closer to the imaging device 2, such that advantages in respect of dynamic characteristics are afforded and a higher performance becomes attainable in the control of the relative position of imaging device 2 and mask 1.

Overall, the design can also be made significantly more compact by virtue of the measures disclosed and exchange of the imaging device 2 in the field, i.e. at the site of use of a corresponding mask inspection device 100, is simplified.

By virtue of the fact that the measurement beams of the interferometers 7 are guided obliquely in the example shown, it may be necessary to carry out an intermediate calculation in order to be able to ascertain the correct relative movement of imaging device 2 and mask 1 with respect to one another.

FIG. 4 shows another variant in which the interferometers are embodied in such a way that that measurement beam which reaches the imaging device 2 proceeds completely in the vacuum chamber 4. In this case, the transmitting-receiving parts 10 of the interferometers 7 are inserted into the partition wall 11 and the radiation windows 16 for the measurement beam for the mask 1 are arranged in the associated vacuum chamber 5, whereas the radiation chambers 16′ for the measurement beam for the imaging device 2 are arranged in the associated vacuum chamber 4. It may be necessary in this case to implement a special encapsulation of the transmitting-receiving parts 10 of the interferometers 7.

Other embodiments are within the scope of the following claims.

### LIST OF REFERENCE SIGNS

1 Element, mask
2 Imaging device
3 Image sensor
4 First partial volume
5 Second partial volume
6 Opening
7 Interferometer
8 Decoupling element
9 Reference element
10 Transmitting/receiving part
11 Partition wall
15 Reference mark, sensor target
16,16′ Radiation window
100 Optical inspection device

What is claimed is:

1. An optical inspection device for elements pertaining to semiconductor lithography,
comprising an imaging device for generating an image of an element, said imaging device being arranged in a first partial volume, and
a second partial volume comprising a holding device for receiving the element,
wherein a separating element is arranged between the two partial volumes,
and further comprising at least one position measuring device for ascertaining the position and orientation of the imaging device and the holding device,
wherein the position measuring device comprises reference marks for emission of electromagnetic radiation used in the position measuring device,
wherein the reference marks are respectively connected to the imaging device and the holding device,
wherein the separating element comprises a partition wall having an opening, wherein the opening serves for image recording by the imaging device and wherein the electromagnetic radiation which emanates from the reference mark mounted on the imaging device and proceeds in the position measuring device passes through the opening.

2. The optical inspection device of claim 1,
characterized in that
at least two position measuring devices and at least two reference marks mounted on the imaging device are present, wherein the beam paths of the electromagnetic radiation which emanates from the reference marks and proceeds in the position measuring devices extend obliquely with respect to one another.

3. The optical inspection device of claim 2,
characterized in that
the beam paths of the electromagnetic radiation which emanates from the reference marks and proceeds in the position measuring devices cross one another.

4. The optical inspection device of claim 1,
characterized in that
the optical inspection device is a mask inspection system for photomasks pertaining to EUV lithography.

5. The optical inspection device of claim 1,
characterized in that
the position measuring device is an interferometer.

6. The optical inspection device of claim 4,
characterized in that the position measuring device is an interferometer.

7. The optical inspection device of claim 2,
characterized in that
the optical inspection device is a mask inspection system for photomasks pertaining to EUV lithography.

8. The optical inspection device of claim 7,
characterized in that
the position measuring device is an interferometer.

9. The optical inspection device of claim 3,
characterized in that
the optical inspection device is a mask inspection system for photomasks pertaining to EUV lithography.

10. The optical inspection device of claim 9,
characterized in that
the position measuring device is an interferometer.
